(19) United States
(12) Patent Application Publication
(10) Pub. No.: US 2022/0302206 A1
(43) Pub. Date: Sep. 22, 2022

(54) MAGNETIC MEMORY DEVICE

(71) Applicant: Kioxia Corporation, Tokyo (JP)

(72) Inventor: Yoshinori KUMURA, Seoul (KR)

(73) Assignee: Kioxia Corporation, Tokyo (JP)

(21) Appl. No.: 17/833,020

(22) Filed: Jun. 6, 2022

Related U.S. Application Data
(62) Division of application No. 16/353,520, filed on Mar. 14, 2019.

(30) Foreign Application Priority Data
Sep. 13, 2018 (JP) 2018-171462

(51) Int. Cl. H01L 27/22; H01L 43/12

(52) U.S. Cl. CPC H01L 27/224; H01L 43/12; H01L 43/02

(57) ABSTRACT

According to one embodiment, a magnetic memory device includes a first interconnect, a second interconnect provided on the upper layer side of the first interconnect, a third interconnect provided on the upper layer side of the second interconnect, a first memory cell provided between the first interconnect and the second interconnect and including a first stacked structure including a magnetic layer, a second memory cell provided between the second interconnect and the third interconnect and including a second stacked structure including a magnetic layer, and a light reflection layer provided on the upper layer side of the first interconnect and on the lower layer side of the third interconnect and having optical reflectance higher than optical transmittance.

### CROSS-REFERENCE TO RELATED APPLICATIONS

This application is a Divisional Application of U.S. application Ser. No. 16/353,520, filed Mar. 14, 2019, which is based upon and claims the benefit of priority from Japanese Patent Application No. 2018-171462, filed Sep. 13, 2018, the entire contents of all of which are incorporated herein by reference.

### FIELD

Embodiments described herein relate generally to a magnetic memory device.

### BACKGROUND

A magnetic memory device (semiconductor integrated circuit device) in which magnetoresistive elements and elements having a switching function of selecting a magnetoresistive element are provided on a semiconductor substrate is proposed.

In the above-mentioned magnetic memory device, in order to enhance the degree of integration, stacking of memory cells each of which includes magnetoresistive elements and element having a switching function is proposed.

However, heretofore, it could have hardly been said that optimization of the structure at the time of stacking of memory cells has sufficiently been carried out.

### BRIEF DESCRIPTION OF THE DRAWINGS

FIG. 1 is a bird's-eye view schematically showing the outline configuration of a magnetic memory device used in a first embodiment.

FIG. 2 is a cross-sectional view schematically showing the outline configuration of the magnetic memory device used in the first embodiment.

FIG. 3A is a cross-sectional view schematically showing a fundamental first configuration example of each of a first stacked structure and second stacked structure.

FIG. 3B is a cross-sectional view schematically showing a fundamental second configuration example of each of the first stacked structure and second stacked structure.

FIG. 4 is a cross-sectional view schematically showing a first configuration example of the magnetic memory device according to the first embodiment.

FIG. 5 is a view showing the heat treatment to be carried out after forming a second memory cell film according to the first configuration example of the first embodiment.

FIG. 6 is a view showing the heat treatment to be carried out after forming the second memory cell film according to a second configuration example of the first embodiment.

FIG. 7 is a view showing the spectral emissivity characteristics of a halogen lamp according to the first embodiment.

FIG. 8 is a view showing the reflectance characteristics of various materials according to the first embodiment.

FIG. 9 is a cross-sectional view schematically showing the configuration of a magnetic memory device according to a second embodiment.

FIG. 10 is a view showing the heat treatment to be carried out after forming a second memory cell film according to the second embodiment.

FIG. 11A is a cross-sectional view schematically showing a first configuration example of a magnetic memory device according to a third embodiment.

FIG. 11B is a cross-sectional view schematically showing a second configuration example of the magnetic memory device according to the third embodiment.

FIG. 12 is a view showing the heat treatment to be carried out after forming a second memory cell film according to the third embodiment.

FIG. 13 is a cross-sectional view schematically showing a first configuration example of a magnetic memory device according to a fourth embodiment.

FIG. 14 is a view showing the heat treatment to be carried out after forming a second memory cell film according to the fourth embodiment.

FIG. 15 is a cross-sectional view schematically showing a second configuration example of the magnetic memory device according to the fourth embodiment.

FIG. 16 is a cross-sectional view schematically showing the second configuration example of the magnetic memory device according to the fourth embodiment.

FIG. 17 is a cross-sectional view schematically showing a modification example of the second configuration example of the magnetic memory device according to the fourth embodiment.

FIG. 18 is a view showing the heat treatment to be carried out after forming a second memory cell film according to a fifth embodiment.

### DETAILED DESCRIPTION

In general, according to one embodiment, a magnetic memory device includes: a first interconnect; a second interconnect provided on the upper layer side of the first interconnect; a third interconnect provided on the upper layer side of the second interconnect; a first memory cell provided between the first interconnect and the second interconnect and including a first stacked structure including a magnetic layer; a second memory cell provided between the second interconnect and the third interconnect and including a second stacked structure including a magnetic layer; and a light reflection layer provided on the upper layer side of the first interconnect and on the lower layer side of the third interconnect and having optical reflectance higher than optical transmittance.

Hereinafter, embodiments will be described with reference to the accompanying drawings.

### Embodiment 1

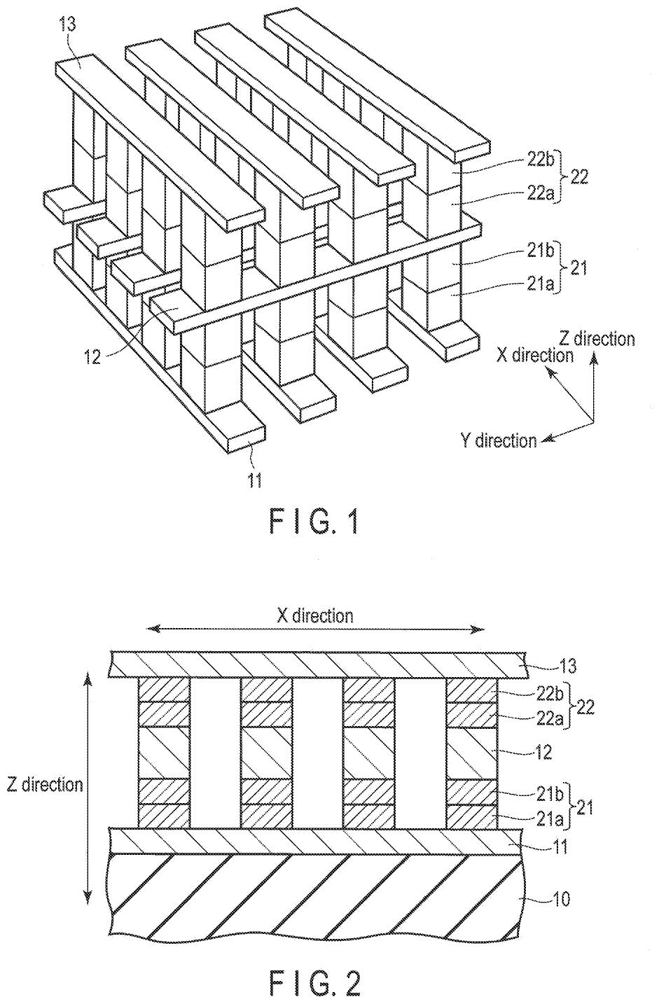

FIG. 1 is a bird's-eye view schematically showing the outline configuration of a magnetic memory device (semiconductor integrated circuit device) used in this embodiment. FIG. 2 is a cross-sectional view schematically showing the outline configuration of the magnetic memory device (semiconductor integrated circuit device) used in this embodiment.

As shown in FIG. 1 and FIG. 2, on an underlying region 10 including a semiconductor substrate and the like, first interconnects 11, second interconnects 12, and third interconnects 13, first memory cells 21, and second memory cells 22 are provided. It should be noted that although not shown in FIG. 1 and FIG. 2, in regions in which the first interconnects 11, second interconnects 12, and third interconnects 13, first memory cells 21, and second memory cells 22 are not provided, insulating regions are provided.

The second interconnects 12 are provided on the upper layer side of the first interconnects 11, and third interconnects 13 are provided on the upper layer side of the second interconnects 12. The first interconnects 11 and third interconnects 13 extend in a first direction, and second interconnects 12 extend in a second direction perpendicular to the first direction. Each of the first memory cells 21 is provided between each of the first interconnect 11 and each of the second interconnect 12, and each of the second memory cells 22 is provided between each of the second interconnects 12 and each of the third interconnects 13. It should be noted that in the drawings, the first direction is shown as the X direction, second direction is shown as the Y direction, and third direction perpendicular to both the first direction and second direction is shown as the Z direction.

The first memory cell 21 includes a first stacked structure 21a including a magnetic layer, and first selector 21b connected to the first stacked structure 21a. Likewise, the second memory cell 22 includes a second stacked structure 22a including a magnetic layer, and second selector 22b connected to the second stacked structure 22a. It should be noted that although in FIG. 1 and FIG. 2, the first stacked structure 21a is provided on the lower layer side of the first selector 21b, the first stacked structure 21a may also be provided on the upper layer side of the first selector 21b. Likewise, although in FIG. 1 and FIG. 2, the second stacked structure 22a is provided on the lower layer side of the second selector 22b, the second stacked structure 22a may also be provided on the upper layer side of the second selector 22b.

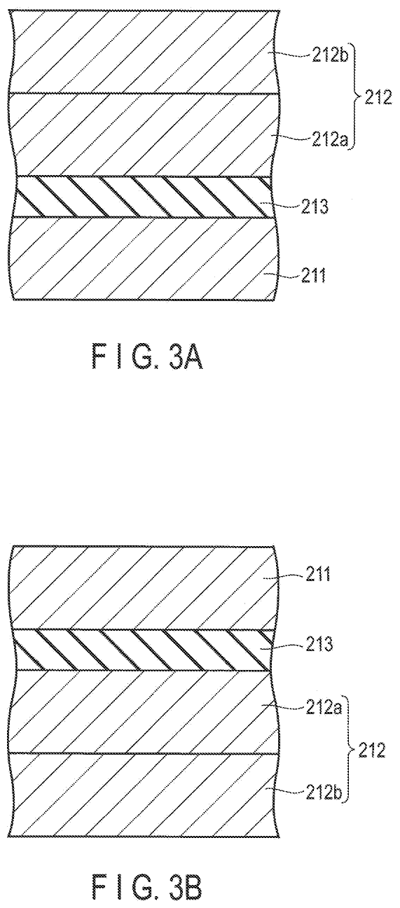

FIG. 3A is a cross-sectional view schematically showing a fundamental first configuration example of each of the first stacked structure 21a and second stacked structure 22a.

Each of the first stacked structure 21a and second stacked structure 22a functions as a spin transfer torque magnetoresistive element having perpendicular magnetization, and includes a first magnetic layer 211 having a variable magnetization direction, second magnetic layer 212 having a fixed magnetization direction, and nonmagnetic layer 213 provided between the first magnetic layer 211 and second magnetic layer 212. The variable magnetization direction implies that the magnetization direction changes with respect to a predetermined write current. The fixed magnetization direction implies that the magnetization direction does not change with respect to a predetermined write current.

The first magnetic layer 211 functions as a storage layer of the magnetoresistive element. The first magnetic layer 211 contains therein at least iron (Fe) and boron (B). The first magnetic layer 211 may further contain therein cobalt (Co) in addition to iron (Fe) and boron (B).

The second magnetic layer 212 functions as a reference layer of the magnetoresistive element. The second magnetic layer 212 includes a first sub-magnetic layer 212a and second sub-magnetic layer 212b. The first sub-magnetic layer 212a contains therein at least iron (Fe) and boron (B). The first sub-magnetic layer 212a may further contain therein cobalt (Co) in addition to iron (Fe) and boron (B). The second sub-magnetic layer 212b contains therein cobalt (Co) and at least one element selected from platinum (Pt), nickel (Ni), and palladium (Pd).

The nonmagnetic layer 213 functions as a tunnel barrier layer of the magnetoresistive element. The nonmagnetic layer 213 contains therein magnesium (Mg) and oxygen (O).

It should be noted that in each of the stacked structures (first stacked structure 21a and second stacked structure 22a), a third magnetic layer (shift-canceling layer) configured to cancel magnetization to be applied from the second magnetic layer (reference layer) 212 to the first magnetic layer (storage layer) 211 may further be included.

Further, in the example shown in FIG. 3A, although the stacking order of the stacked structures (first stacked structure 21a and second stacked structure 22a) is the order of the first magnetic layer 211, nonmagnetic layer 213, and second magnetic layer 212, the order may be the order of the second magnetic layer 212, nonmagnetic layer 213, and first magnetic layer 211 as shown in FIG. 3B.

The first selector 21b shown in FIG. 1 and FIG. 2 is used to select the first stacked structure 21a, and second selector 22b is used to select the second stacked structure 22a. Each of the first selector 21b and second selector 22b functions as a switch between two terminals. For example, when a voltage to be applied between two terminals is less than a threshold voltage, the two-terminal switching element is in the high-resistance state (for example, electrically non-conductive state). When a voltage to be applied between the two terminals is larger than the threshold voltage, the two-terminal type switching element is in the low-resistance state (for example, electrically conductive state). The two-terminal switch element may have the above-mentioned function in both directions.

The above-mentioned switching element may contain therein at least one chalcogen element selected from a group constituted of Te, Se, and S.

Alternatively, the switching element may contain therein a chalcogenide which is a chemical compound containing therein these chalcogen elements. Further, the above-mentioned switching element may contain therein at least one element selected from a group constituted of B, Al, Ga, In, C, Si, Ge, Sn, As, P, and Sb.

In the manufacture of the magnetic memory device having the above-mentioned configuration, the first memory cell 21 on the lower layer side undergoes more heat treatment processes than the second memory cell 22 on the upper layer side. That is, the first stacked structure 21a undergoes more heat treatment processes than the second stacked structure 22a. For this reason, there is sometimes a case where the characteristics of the first memory cell 21 (first stacked structure 21a) deteriorates or case where a difference in characteristics occurs between the first memory cell 21 (first stacked structure 21a) and second memory cell 22 (second stacked structure 22a). When such a deterioration in characteristics or difference in characteristics occurs, it becomes difficult to obtain a magnetic memory device having the desired performance.

In this embodiment, in order to reduce the above-mentioned problem, the following configuration is proposed.

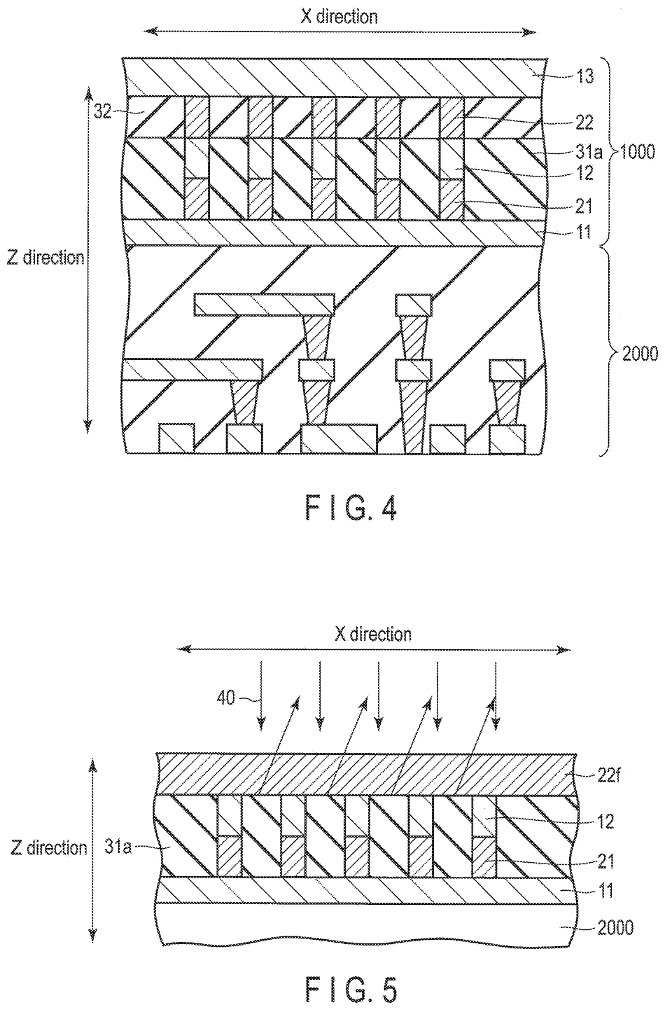

FIG. 4 is a cross-sectional view schematically showing a first configuration example of this embodiment.

As shown in FIG. 4, a memory cell region 1000 is provided on a peripheral circuit region (formed of transistors and interconnects and the like) 2000.

In the memory cell region 1000, a light reflection layer 31a is provided. The light reflection layer 31a includes a part provided between the first interconnect 11 and third interconnect 13. That is, the light reflection layer 31a is provided on the upper layer side of the first interconnect 11 and on the lower layer side of the third interconnect 13. In this configuration example, the light reflection layer 31a is provided on the upper layer side of the first interconnect 11 and on the lower layer side of the second memory cell 22. It is desirable that the top surface of the light reflection layer 31a be provided on the upper layer side of the first memory cell 21. Further, in this configuration example, an interlayer insulating film 32 is provided between the light reflection layer 31a and third interconnect 13. The light reflection layer 31a has optical reflectance higher than the optical transmittance, and is formed of an oxide of aluminum. More specifically, the light reflection layer 31a has optical reflectance higher than the optical transmittance with respect to light of a halogen lamp to be described later.

As described above, by providing the light reflection layer 31a, it is possible, when the second memory cells 22 on the upper layer side are subjected to heat treatment, to reduce the influence of the heat treatment on the first memory cells 21 on the lower layer side.

FIG. 5 is a view showing the heat treatment to be carried out after forming a second memory cell film 22f. More specifically, FIG. 5 is a view showing the heat treatment to be carried out after forming a second stacked structure film. As the heat treatment, halogen lamp annealing is used. For example, halogen lamp annealing at, for example, 400° C. for about 30 seconds is carried out. Part of the lamp light 40 is absorbed by the second memory cell film 22f, whereby the second memory cell film 22f is heat-treated. The most part of the lamp light 40 which has been transmitted through the second memory cell film 22f is reflected from the light reflection layer 31a, and hence the lamp light 40 hardly reaches the first memory cells 21. Accordingly, it is possible to significantly prevent the first memory cells 21 from being heated.

Next, a second configuration example of this embodiment will be described below. It should be noted that the fundamental items are identical to the first configuration example, and hence descriptions of the items already described in the first configuration example are omitted.

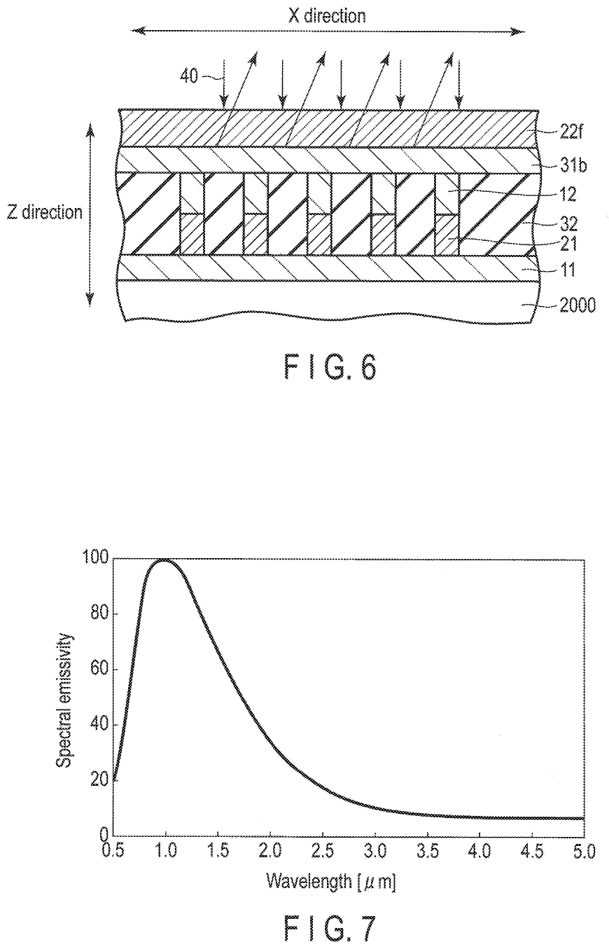

FIG. 6 is a view showing the heat treatment to be carried out after forming the second memory cell film 22f. More specifically, FIG. 6 is a view showing the heat treatment to be carried out after forming the second stacked structure film. In this configuration example, a light reflection layer 31b is formed on the interlayer insulating film 32 and second interconnects 12, and the second memory cell film 22f is formed on the light reflection layer 31b. The light reflection layer 31b has higher optical reflectance than the optical transmittance with respect to the light of a halogen lamp. The light reflection layer 31b is formed of aluminum (Al) or copper (Cu). Part of the lamp light 40 is absorbed by the second memory cell film 22f, whereby the second memory cell film 22f is heated. The most part of the lamp light 40 which has been transmitted through the second memory cell film 22f is reflected from the surface of the light reflection layer 31b, and hence the lamp light 40 hardly reaches the first memory cells 21. Accordingly, it is possible to significantly prevent the first memory cells 21 from being heated.

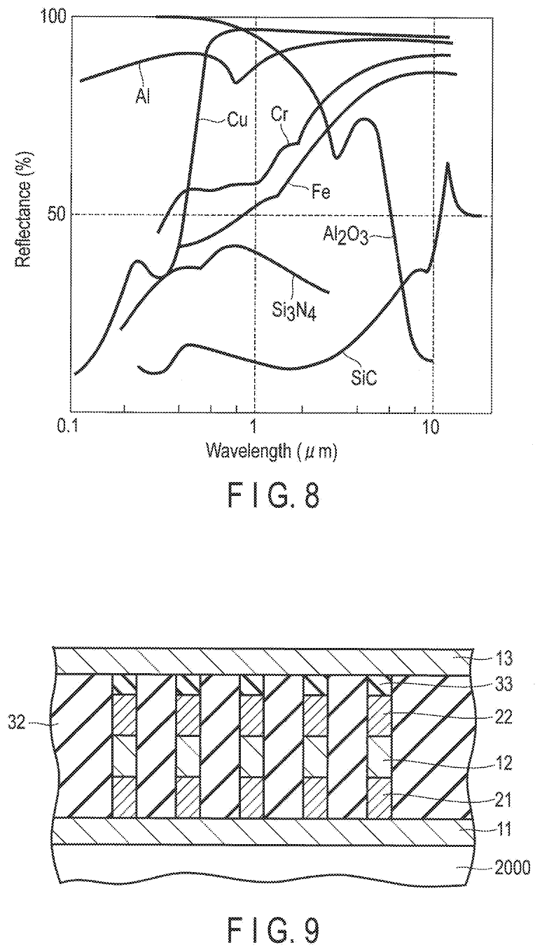

FIG. 7 is a view showing the spectral emissivity characteristics of a halogen lamp. FIG. 8 is a view showing the reflectance characteristics of various materials. As can be seen from FIG. 7 and FIG. 8, the aforementioned aluminum oxide (Al₂O₃), aluminum (Al), and copper (Cu) have high reflectance at the peak wavelength (1 μm) of the spectral emissivity of the halogen lamp.

As described above, in this embodiment, by providing the light reflection layer 31a or 31b on the upper layer side of the first interconnects 11 and on the lower layer side of the third interconnects 13, it is possible to prevent the first memory cells 21 (particularly, first stacked structures 21a) from being heated, and obtain a magnetic memory device having excellent performance.

### Embodiment 2

Next, a second embodiment will be described below. It should be noted that the fundamental items are identical to the first embodiment, and hence descriptions of the items already described in the first embodiment are omitted.

FIG. 9 is a cross-sectional view schematically showing the configuration of a magnetic memory device (semiconductor integrated circuit device) according to the second embodiment.

In this embodiment, a light-absorbing layer 33 is provided on the upper layer side of the second interconnects 12 and on the lower layer side of the third interconnects 13. In the example shown in FIG. 9, the light-absorbing layer 33 is provided on the upper layer side of the second memory cells 22. The light-absorbing layer 33 has higher optical absorptance than the optical transmittance. More specifically, the light-absorbing layer 33 has higher optical absorptance than the optical transmittance with respect to the halogen lamp light. The light-absorbing layer 33 is formed of silicon nitride (SiN) or silicon carbide (SiC).

As described above, by providing the light-absorbing layer 33, it is possible, when the second memory cells 22 on the upper layer side are subjected to heat treatment, to reduce the influence of the heat treatment on the first memory cells 21 on the lower layer side.

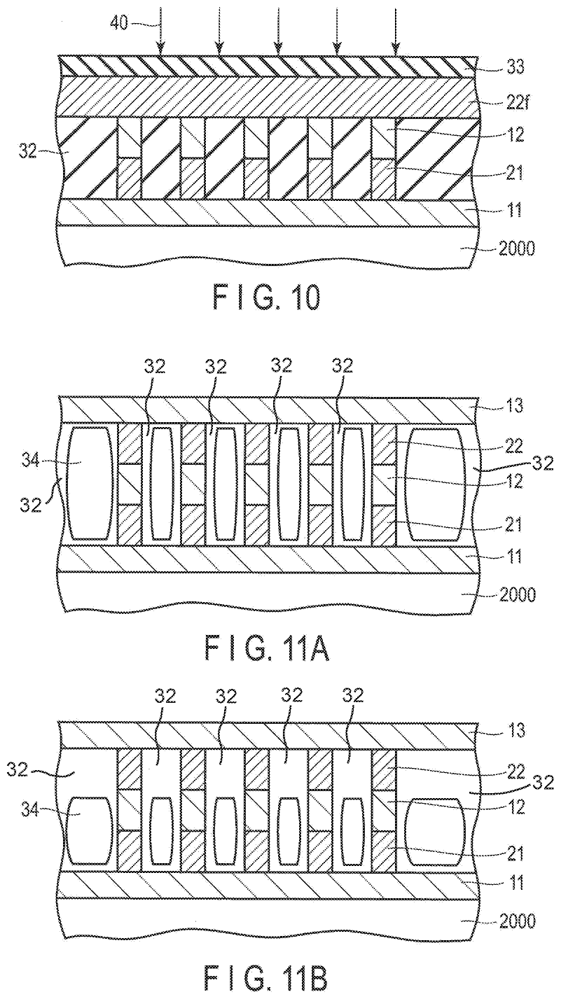

FIG. 10 is a view showing the heat treatment to be carried out after forming the second memory cell film 22f. More specifically, FIG. 10 is a view showing the heat treatment to be carried out after forming the second stacked structure film. As the heat treatment, halogen lamp annealing is used. The most part of the lamp light 40 is absorbed by the light-absorbing layer 33, and the second memory cell film 22f is heat-treated by the heat generated in the light-absorbing layer 33. The most part of the lamp light 40 is absorbed by the light-absorbing layer 33, and hence the lamp light 40 hardly reaches the first memory cells 21. Accordingly, it is possible to significantly prevent the first memory cells 21 from being heated.

As described above, in this embodiment, by providing the light-absorbing layer 33 on the upper layer side of the second interconnects 12 and on the lower layer side of the third interconnects 13, it is possible to prevent the first memory cells 21 (particularly, first stacked structures 21a) from being heated, and obtain a magnetic memory device having excellent performance.

### Embodiment 3

Next, a third embodiment will be described below. It should be noted that the fundamental items are identical to the first embodiment, and hence descriptions of the items already described in the first embodiment are omitted.

FIG. 11A and FIG. 11B are cross-sectional views schematically showing a first configuration example and second configuration example of a magnetic memory device (semiconductor integrated circuit device) according to the third embodiment.

In this embodiment, cavities 34 are provided on the upper layer side of the first interconnects 11 and on the lower layer side of the third interconnects 13. As shown in FIG. 11A and FIG. 11B, positions at which the cavities 34 are formed change according to the embedding characteristics of the cavities 34.

As described above, by providing the cavities 34, it is possible, when the memory cells 22 on the upper side are subjected to heat treatment, to reduce the influence of the heat treatment on the first memory cells 21 on the lower layer side.

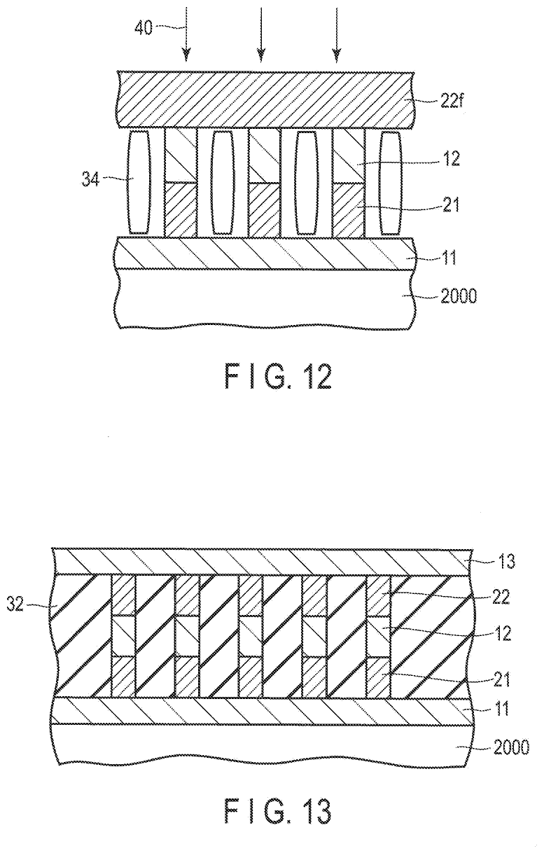

FIG. 12 is a view showing the heat treatment to be carried out after forming the second memory cell film 22f. More specifically, FIG. 12 is a view showing the heat treatment to be carried out after forming the second stacked structure film. As the heat treatment, halogen lamp annealing is used. The second memory cell film 22f is heated by the lamp light 40, whereby the second memory cell film 22f is heat-treated. On the other hand, cavities 34 are provided on the lower layer side of the second memory cell film 22f, and hence the heat generated in the second memory cell film 22f is hardly transmitted to the first memory cells 21. Accordingly, it is possible to significantly prevent the first memory cells 21 from being heated.

As described above, in this embodiment, by providing the cavities 34, it is possible to prevent the first memory cells 21 (particularly, first stacked structures 21a) from being heated, and obtain a magnetic memory device having excellent performance.

### Embodiment 4

Next, a fourth embodiment will be described below. It should be noted that the fundamental items are identical to the first embodiment, and hence descriptions of the items already described in the first embodiment are omitted.

FIG. 13 is a cross-sectional view schematically showing a first configuration example of a magnetic memory device (semiconductor integrated circuit device) according to a fourth embodiment.

In this embodiment, the second interconnects 12 have lower thermal conductivity than the first interconnects 11. Further, it is desirable that the second interconnects 12 should have lower thermal conductivity than the third interconnects 13. As the material for the second interconnects 12, it is possible to use titanium (Ti) or Nichrome (Ni).

As described above, by forming the second interconnects 12 out of a material having low thermal conductivity, it is possible, when the second memory cells 22 on the upper layer side are subjected to heat treatment, to reduce the influence of the heat treatment on the first memory cells 21 on the lower layer side.

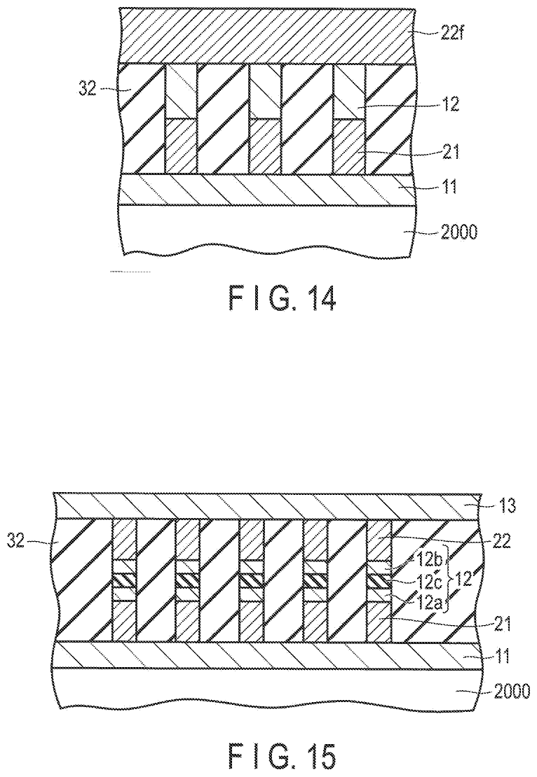

FIG. 14 is a view showing the heat treatment to be carried out after forming the second memory cell film 22f. More specifically, FIG. 14 is a view showing the heat treatment to be carried out after forming the second stacked structure film. As the heat treatment, halogen lamp annealing is used. The second memory cell film 22f is heated by the lamp light 40, whereby the second memory cell film 22f is heat-treated. Because the second interconnects 12 formed of a material having low thermal conductivity are provided between the first memory cells 21 and second memory cell film 22f, the heat generated in the second memory cell film 22f is hardly conducted to the first memory cells 21. Accordingly, it is possible to significantly prevent the first memory cells 21 from being heated.

Next, a second configuration example of this embodiment will be described below. It should be noted that the fundamental items are identical to the first configuration example, and hence descriptions of the items already described in the first configuration example are omitted.

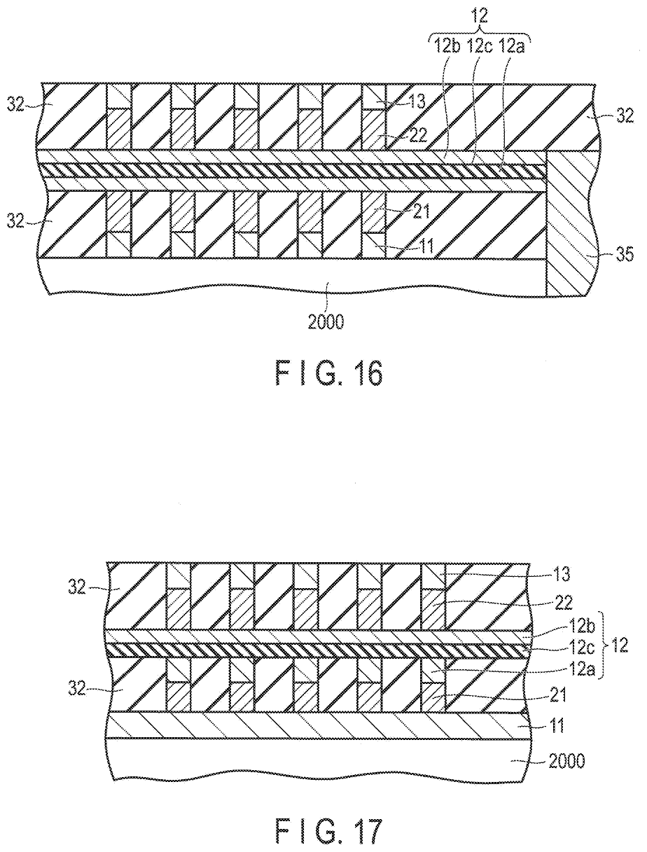

Each of FIG. 15 and FIG. 16 is a cross-sectional view schematically showing the second configuration example of the magnetic memory device according to the fourth embodiment. The direction of the cross section shown in FIG. 15 and direction of the cross section shown in FIG. 16 are perpendicular to each other. In this configuration example, the second interconnect 12 is constituted of a first electrically conductive part 12a, second electrically conductive part 12b, and insulating part 12c between the first electrically conductive part 12a and second electrically conductive part 12b. As shown in FIG. 16, the first electrically conductive part 12a and second electrically conductive part 12b are connected to each other by a conductive connecting part 35 at an end part of the second interconnect 12. Accordingly, although the insulating part 12c is interposed between the first electrically conductive part 12a and second electrically conductive part 12b, the second interconnect 12 substantially functions as an interconnect. In this configuration example, thermal conduction is suppressed by the insulating part 12c, and hence it is possible to significantly prevent the first memory cells 21 from being heated.

FIG. 17 is a cross-sectional view schematically showing a modification example of the second configuration example. In this modification example, the interconnects are completely separated from each other by the insulating film 12c. In this case, by making the insulating film 12c thicker, it is possible to further suppress the thermal conduction.

As described above, in this embodiment, by providing the second interconnects 12 including the material having low thermal conductivity, it is possible to prevent the first memory cells 21 (particularly, first stacked structures 21a) from being heated, and obtain a magnetic memory device having excellent performance.

### Embodiment 5

Next, a fifth embodiment will be described below. It should be noted that the fundamental items are identical to the first to fourth embodiments, and hence descriptions of the items already described in the first to fourth embodiments are omitted.

In the above-mentioned first to fourth embodiments, although halogen lamp annealing is used as lamp annealing, in this embodiment, flash-lamp annealing is used as lamp annealing.

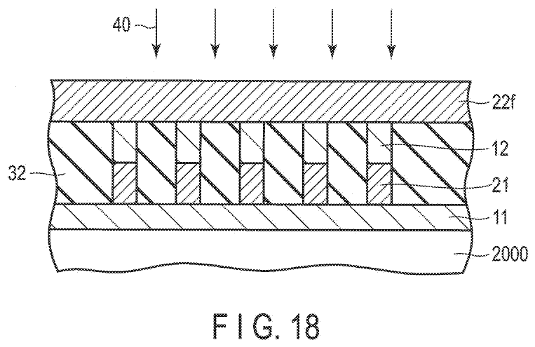

FIG. 18 is a view showing the heat treatment to be carried out after forming the second memory cell film 22f. More specifically, FIG. 18 is a view showing the heat treatment to be carried out after forming the second stacked structure film. After forming the second memory cell film 22f, heat treatment is carried out by means of flash-lamp light.

In the heat treatment described in the first to fourth embodiments, heat treatment is completed within an extremely short time by using the flash-lamp annealing, and hence it becomes possible to further prevent the heat from being conducted to the lower layer side. As a result, it is possible to prevent the first memory cells 21 (particularly, first stacked structures 21a) from being heated, and obtain a magnetic memory device having excellent performance.

Further, in each of the aforementioned embodiments, although the description has been given of the case where a two-terminal type switching element is applied to the selector, a field-effect transistor such as a metal oxide semiconductor (MOS) transistor, FIN-type transistor, and the like each of which is a three-terminal type switching element may be applied to the selector. Further, a two-terminal type element having a diode function may also be applied.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory device comprising:
a first interconnect;
a second interconnect provided on the upper layer side of the first interconnect;
a third interconnect provided on the upper layer side of the second interconnect;
a first memory cell provided between the first interconnect and the second interconnect and including a first stacked structure including a magnetic layer;
a second memory cell provided between the second interconnect and the third interconnect and including a second stacked structure including a magnetic layer; and
a light reflection layer provided on the upper layer side of the first interconnect and on the lower layer side of the third interconnect and having optical reflectance higher than optical transmittance.

2. The device of claim 1, wherein
the light reflection layer is formed of aluminum oxide, aluminum or copper.

3. The device of claim 1, wherein
the first memory cell further includes a first switching element connected to the first stacked structure, and
the second memory cell further includes a second switching element connected to the second stacked structure.

4. The device of claim 1, wherein
each of the first stacked structure and the second stacked structure includes a first magnetic layer having a variable magnetization direction, a second magnetic layer having a fixed magnetization direction, and a nonmagnetic layer provided between the first magnetic layer and the second magnetic layer.
